(19) United States
(12) Patent Application Publication
(10) Pub. No.: US 2010/0147563 A1
(43) Pub. Date: Jun. 17, 2010

(54) SUBSTRATE HAVING ELECTROMAGNETIC SHIELDING MEMBER

(75) Inventors: Young Po Park, Gyeongsangnam-do (KR); Going Sik Kim, Busan (KR); Hwan Yong Jung, Gyeongsangnam-do (KR); Ha II Kim, Seoul (KR); Dong Gi An, Gyeongsangnam-do (KR); Myeong Hui Jung, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO MECHANICS CO., LTD., Suwon (KR)

(21) Appl. No.: 12/476,802

(22) Filed: Jun. 2, 2009

(30) Foreign Application Priority Data
Dec. 11, 2008 (KR) 10-2008-0126055

(51) Int. Cl. H05K 1/11

(52) U.S. Cl. 174/254; 174/261

(57) ABSTRACT

Disclosed is a substrate having an electromagnetic shielding member, which includes a first circuit layer connected to a ground layer, a coverlay formed on the first circuit layer, an electromagnetic shielding member formed on the coverlay, and a first via formed in the coverlay to connect the electromagnetic shielding member to the first circuit layer, so that the electromagnetic shielding member and the ground layer are connected to each other through a via structure, thereby preventing the electromagnetic shielding member from becoming cracked due to the stepped portion of the substrate.

### CROSS REFERENCE TO RELATED APPLICATION

This application claims the benefit of Korean Patent Application No. 10-2008-0126055, filed Dec. 11, 2008, entitled “A substrate having an electromagnetic shielding member”, which is hereby incorporated by reference in its entirety into this application.

### BACKGROUND OF THE INVENTION

1. Field of the Invention

The present invention relates to a substrate having an electromagnetic shielding member.

2. Description of the Related Art

In electronic apparatuses such as mobile phones, digital cameras, notebook computers, etc., which have rapidly evolved such that the size thereof is reduced and the functionality thereof is increased, a flexible printed circuit board (FPCB) is chiefly employed to provide complicated units and circuits in a narrow space. In particular, an FPCB is mainly utilized in AMOLED display fields and liquid crystal displays (LCDs).

Typically, an FPCB includes a plurality of signal lines, and such signal lines function as an antenna, thus generating electromagnetic interference (EMI).

Hence, electromagnetic shielding methods for solving EMI are required. For instance, when the number of grounds is increased to solve problems of EMI and electrostatic discharge, the cost is increased and the connection to a PCB becomes difficult. Also, defects may be easily caused on the FPCB.

FIG. 1 is a schematic cross-sectional view showing a conventional electromagnetic shielding FPCB.

As shown in FIG. 1, a conventional electromagnetic shielding flexible substrate 10 includes a first metal layer 12, a coverlay 14 formed on the first metal layer 12, an insulating layer 16 and a second metal layer 18 sequentially formed on part of the coverlay 14, and an electromagnetic shielding film 22 for achieving an electromagnetic shielding function.

Because the insulating layer 16 and the second metal layer 18 are formed on part of the coverlay 14, a high stepped portion may result. Also, the electromagnetic shielding film 22 is curved and disposed so that the second metal layer 18 is connected to a ground layer 20 through the electromagnetic shielding film 22.

In the case where the conventional electromagnetic shielding exible substrate 10 has a high stepped portion, a crack is generated at the curved portion of the electromagnetic shielding film 22, and thus a good electromagnetic shielding function is not achieved.

A component for achieving an electromagnetic shielding function, serving as the member for achieving an electromagnetic shielding function in lieu of the electromagnetic shielding film, may be formed through a sputtering process. However, in the case where the substrate has a high stepped portion, it is difficult to perform a sputtering process at the stepped portion.

Hence, the case where the substrate including the flexible substrate has a high stepped portion needs a new structure for achieving the electromagnetic shielding function.

### SUMMARY OF THE INVENTION

Therefore, the present invention has been made keeping in mind the problems encountered in the related art and provides a substrate having an electromagnetic shielding member, which is capable of preventing the cracking of the electromagnetic shielding member.

An aspect of the present invention provides a substrate having an electromagnetic shielding member, including a first circuit layer connected to a ground layer, a coverlay formed on the first circuit layer, an electromagnetic shielding member formed on the coverlay, and a first via formed in the coverlay to connect the electromagnetic shielding member and the first circuit layer to each other.

In the substrate, an insulating layer and a second circuit layer may be formed on part of the coverlay, and a second via may be formed to pass through the insulating layer and the coverlay so that the second circuit layer is electrically connected to the first circuit layer.

In the substrate, the electromagnetic shielding member may be formed using an electromagnetic shielding film or nano-silver.

Another aspect of the present invention provides a substrate having an electromagnetic shielding member, including a flexible substrate having a polyimide layer and an inner circuit layer formed on the polyimide layer, a coverlay formed on the flexible substrate, a rigid substrate formed on the coverlay and having a window, an electromagnetic shielding member formed on the coverlay exposed by the window, and a first via formed to pass through the coverlay exposed by the window so that the electromagnetic shielding member and the inner circuit layer are connected to each other.

In the substrate, the rigid substrate may include an insulating layer and a circuit layer, and formed in the rigid substrate may be a second via passing through the insulating layer and the coverlay provided under the rigid substrate so that the circuit layer and a base circuit layer are connected to each other.

In the substrate, the electromagnetic shielding member may be formed using an electromagnetic shielding film or nano-silver.

The features and advantages of the present invention will be more clearly understood from the following detailed description taken in conjunction with the accompanying drawings.

Further, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

### BRIEF DESCRIPTION OF THE DRAWINGS

FIG. 1 is a schematic cross-sectional view showing a conventional FPCB having an electromagnetic shielding film;

FIG. 2 is a schematic cross-sectional view showing a substrate having an electromagnetic shielding member according to a first embodiment of the present invention; and

FIG. 3 is a schematic cross-sectional view showing a substrate having an electromagnetic shielding member according to a second embodiment of the present invention.

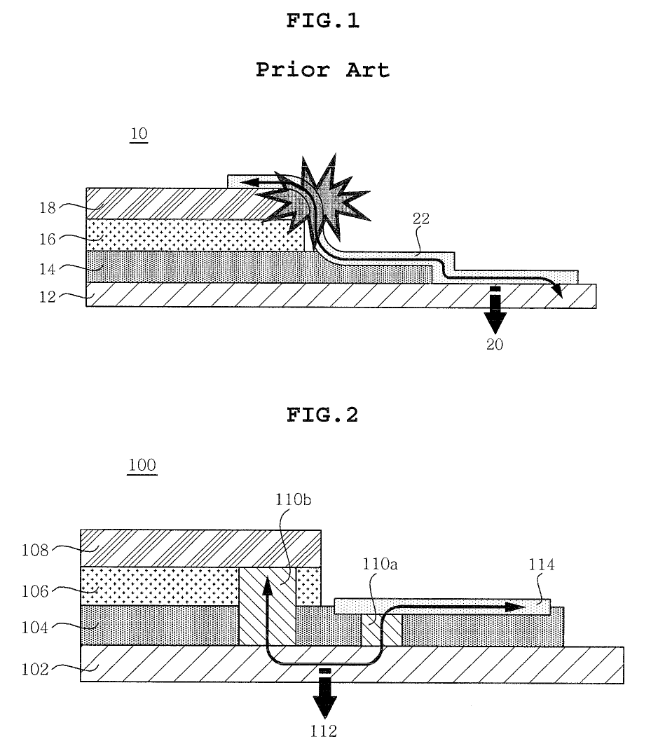

### DESCRIPTION OF THE PREFERRED EMBODIMENTS

The features and advantages of the present invention will be more clearly understood from the following detailed description and embodiments taken in conjunction with the accompanying drawings. Throughout the drawings, the same reference numerals refer to the same or similar elements, and redundant descriptions are omitted. In order to make the characteristics of the invention clear and for the convenience of description, a detailed description pertaining to the other known techniques may be omitted.

Hereinafter, a detailed description will be given of the embodiments of the present invention, with reference to the accompanying drawings.

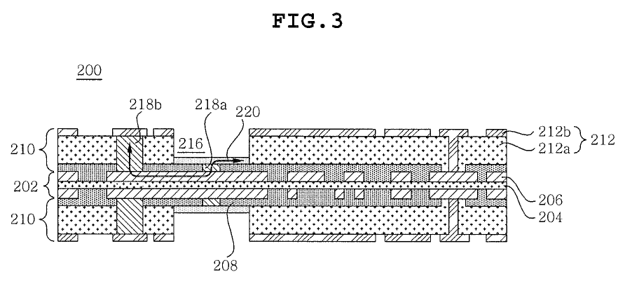

FIG. 2 is a schematic cross-sectional view showing a substrate having an electromagnetic shielding member according to a first embodiment of the present invention, and FIG. 3 is a schematic cross-sectional view showing a substrate having an electromagnetic shielding member according to a second embodiment of the present invention.

With reference to FIG. 2 schematically showing the substrate having an electromagnetic shielding member according to the first embodiment of the present invention, the substrate 100 having an electromagnetic shielding member according to the above embodiment is described below.

As shown in FIG. 2, the substrate having the electromagnetic shielding member according to the first embodiment is configured such that a ground layer 112 and an electromagnetic shielding member 114 are connected to each other through a first via 110a.

The substrate 100 having the electromagnetic shielding member includes a first circuit layer 102 connected to a ground layer 112, a coverlay 104 formed on the first circuit layer 102, an electromagnetic shielding member 114 formed on the coverlay 104, and a first via 110a formed in the coverlay 104 so as to connect the electromagnetic shielding member 114 and the first circuit layer 102 to each other.

The electromagnetic shielding member 114 is connected to the ground layer 12 through the first circuit layer 102 by means of the first via 110a which passes through the coverlay 104.

The electromagnetic shielding member 114 may be formed by attaching an electromagnetic shielding film or by sputtering nano-silver.

As shown in FIG. 2, in the case where the substrate 100 having the electromagnetic shielding member has a high stepped portion owing to the formation of an insulating layer 106 and a second circuit layer 108 on part of the coverlay 104, a second via 100b which passes through the insulating layer 106 and the coverlay 104 is formed so that the second circuit layer 108 and the first circuit layer 102 are connected to each other. In this case, because the first circuit layer 102 is connected to the electromagnetic shielding member 114 through the first via 110a, the electromagnetic shielding function may be achieved.

Even when the substrate has a high stepped portion, the substrate is constructed such that the circuit layer is connected to the electromagnetic shielding member 114 using a via structure, thus preventing the cracking of the electromagnetic shielding member 114 and achieving the electromagnetic shielding function.

With reference to FIG. 3 schematically showing the substrate having an electromagnetic shielding member according to the second embodiment of the present invention, the substrate 200 having an electromagnetic shielding member according to the above embodiment is described below.

As shown in FIG. 3, the substrate 200 having the electromagnetic shielding member according to the embodiment of the present invention is applied to a general rigid-flexible substrate in which rigid parts are connected to each other through a flexible part.

The substrate 200 having the electromagnetic shielding member according to the embodiment of the present invention includes a flexible substrate 202 having an inner circuit layer 206, a coverlay 208 formed on the flexible substrate, a rigid substrate 212 having a window 216, and a first via 218a for connecting the electromagnetic shielding member 220 and the inner circuit layer 206 to each other.

The flexible substrate 202 is configured such that the inner circuit layer 206 is formed on one surface or both surfaces of a polyimide layer 204.

The coverlay 208 is used to protect the inner circuit layer 206 of the flexible substrate 202. For example, the coverlay may be temporarily bonded to the inner circuit layer 206 by using manual ironing in the state of its being pre-attached to the inner circuit layer 206 using an adhesive, and then pressed, thereby attaching the coverlay 208 to the inner circuit layer 206. The material for the coverlay 208 may be a polyimide film.

Although the construction in which the coverlay 208 is formed on all of the flexible substrate 202 is illustrated in FIG. 3, a construction in which the coverlay is formed only on part of the flexible substrate 202 constituting the flexible part may also be included in the scope of the present invention.

The rigid substrate 212 is layered on the flexible substrate 202 in a state of having the window 216 for exposing the flexible part, and includes an insulating layer 212a and a circuit layer 212b.

In order to connect the circuit layer 212b of the rigid substrate 212 to the electromagnetic shielding member 220, a second via 218b which passes through the insulating layer 212a and the coverlay 208 formed under the rigid substrate 212 is formed. The second via 218b is connected to the inner circuit layer 206, and the inner circuit layer 206 is connected to the electromagnetic shielding member 220 through the first via 218a, thus achieving the electromagnetic shielding function.

The electromagnetic shielding member 220 may be formed by attaching an electromagnetic shielding film or by sputtering nano-silver.

As described hereinbefore, the present invention provides a substrate having an electromagnetic shielding member. According to the present invention, the electromagnetic shielding member is connected to a ground layer through a via structure, and thereby the electromagnetic shielding member does not become cracked even in the presence of a stepped portion of the substrate.

Also, according to the present invention, the construction of the substrate in which the electromagnetic shielding member is connected to the ground layer through the via structure can be applied to a general rigid-flexible substrate having a stepped portion formed by a window for exposing a flexible part.

Although the embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A substrate having an electromagnetic shielding member, comprising:
a first circuit layer connected to a ground layer;
a coverlay formed on the first circuit layer;
an electromagnetic shielding member formed on the coverlay; and
a first via formed in the coverlay to connect the electromagnetic shielding member and the first circuit layer to each other.

2. The substrate as set forth in claim 1, wherein an insulating layer and a second circuit layer are formed on part of the coverlay, and a second via is formed to pass through the insulating layer and the coverlay so that the second circuit layer is electrically connected to the first circuit layer.

3. The substrate as set forth in claim 1, wherein the electromagnetic shielding member is formed using an electromagnetic shielding film or nano-silver.

4. A substrate having an electromagnetic shielding member, comprising:
a flexible substrate having a polyimide layer and an inner circuit layer formed on the polyimide layer;
a coverlay formed on the flexible substrate;
a rigid substrate formed on the coverlay and having a window;
an electromagnetic shielding member formed on the coverlay exposed by the window; and
a first via formed to pass through the coverlay exposed by the window so that the electromagnetic shielding member and the inner circuit layer are connected to each other.

5. The substrate as set forth in claim 4, wherein the rigid substrate includes an insulating layer and a circuit layer, and formed in the rigid substrate is a second via passing through the insulating layer and the coverlay provided under the rigid substrate so that the circuit layer and a base circuit layer are connected to each other.

6. The substrate as set forth in claim 4, wherein the electromagnetic shielding member is formed using an electromagnetic shielding film or nano-silver.
